(19) United States
(12) Patent Application Publication
(10) Pub. No.: US 2005/0270740 A1
(43) Pub. Date: Dec. 8, 2005

(54) Heat-dissipating structure inside the computer mainframe

(75) Inventors: Chiao-Chih Tai, Taoyuan Hsien (TW); Shih-Wen Chang, Taoyuan Hsien (TW); I-Hsin Peng, Taoyuan Hsien (TW)

Correspondence Address: TROXELL LAW OFFICE PLLC;Suite 1404, 5205 Leesburg Pike, Falls Church, VA, 22041, US

(73) Assignee: Enlight Corporation

(21) Appl. No.: 10/878,995

(22) Filed: Jun. 30, 2004

(30) Foreign Application Priority Data
Jun. 4, 2004 (TW) 93208811

(51) Int. Cl. H05K 7/20

(52) U.S. Cl. 361/690

(57) ABSTRACT

A heat-dissipating structure inside a computer mainframe comprising an air-guiding mask installed either to the side board of a mainframe case or above the heat dissipation module of CPU; when mainframe case is used together with different mother boards, the CPU location within the mother board is expected to change accordingly, but the air-guiding mask can be correlated effectively to the heat-dissipating holes on the mainframe case, cold air can be introduced into the mainframe to dissipate heat, hot air within the mainframe case can be prevented from back flowing into the heat-dissipating module installed above CPU, CPU temperature can therefore be lowered; meanwhile, when air-guiding mask is installed in the mainframe case, a baffle can be installed at the gap between the air-guiding mask and heat-dissipating module such that hot air back flow can be greatly reduced and cold air from exterior can cool CPU directly.

### BACKGROUND OF THE INVENTION

1. Field of the Invention

This invention is related to a heat dissipation structure inside a computer mainframe, it is more specifically related to designs which have the same mainframe case but different mother boards or have CPU located at different locations but heat back flow issue can still be effectively controlled and the entrance temperature of the air can still be effectively reduced.

2. Description of the Related Art

Taking computer as an example, traditionally heat sink is installed above a CPU, it is used to help the release of heat generated by the CPU chip. The heat sink is used to generate convective air, and the heat on the heat-dissipating fin, which is used to absorb heat from heat generation source, is taken away through air convection (through either air extracting or blowing will be depending on the computer internal space available and design requirement) in order to reduce CPU temperature. But in the real test for conventional heat dissipation structure, the fan entrance end has a temperature as high as 46˜47° C., the heat dissipation efficiency is thus limited; since the efficiency in traditional way of heat conduction and heat dissipation cannot meet the requirement of high speed and high power consumption trend today, therefore, to dissipate heat by introducing directly cold air from mainframe case or from other external areas to the heat sink of CPU can have better cooling efficiency, and it is the main stream currently used in the industry, an air-guiding mask need to be installed and fixed on the outer case of motherboard in order to be able to dissipate heat by the above-mentioned method, but here comes the problem, since the CPU location in different mother board is different, therefore, the air-guiding mask fixed above mainframe case can not provide effectively lower temperature air to the heat sink, a problem of hot air back flow inside the mainframe case thus appears.

To solve the problem associated with the conventional heat dissipation structure of CPU, we propose an improvement heat dissipation air-guiding mask structure which possesses direct and universal design and therefore, can effectively cool and reduce the temperature inside the computer mainframe.

### SUMMARY OF THE INVENTION

The main purpose of this invention is to provide a design which can solve the problem associated with CPU location change in different mother boards while the heat dissipation hole location for air entrance on the mainframe case remains unchanged, with the combination of heat dissipation module and CPU, the colder air on the mainframe case can still be effectively introduced into the equipment and the hot air back flow from the inside of mainframe case can be prevented, in this way, the air entrance end temperature on the heat dissipation module can be maintained at low temperature. In addition, if the heat dissipation hole area covered by air-guiding mask is greater than the entrance area of heat-dissipation fan, the air flow speed and air resistance can thus be reduced and heat-dissipation fan efficiency can in turn be enhanced and finally CPU temperature be effectively lowered.

Yet another purpose of this invention is to provide an universal heat-dissipating structure which can be used to cope with the change in mother board, there is no need to develop and invest multiple sets of molds for in a single application, lower manufacturing cost and shorter time-to-the-market can thus be guaranteed.

### BRIEF DESCRIPTION OF THE DRAWINGS

FIG. 1 a stereo diagram showing the appearance of the current invention.

FIG. 2 is a stereo diagram showing a disassembly of all the components.

FIG. 3 is a cross sectional view of the current invention embodied with heat-dissipating and cooling status.

FIG. 4 shows when the CPU has its location changed, the air-guiding mask can still cover the heat-dissipating holes installed on the mainframe case.

FIG. 5 shows a second cross sectional view of the current invention embodied with heat-dissipating and cooling status.

FIG. 6 shows when the CPU has its location changed, the air-guiding mask can still be correlated spatially to the heat-dissipating holes installed on the mainframe case.

FIG. 7 is a disassembly stereo diagram for another embodiment of the current invention.

FIG. 8 shows an embodied heat-dissipating and cooling status in accordance with those illustrated in FIG. 5.

FIG. 9 shows the coverage by air-guiding mask installed in mainframe case when CPU has its location changed.

### DETAILED DESCRIPTION OF THE INVENTION

The detailed embodiments for this invention are described with the help from attached figures:

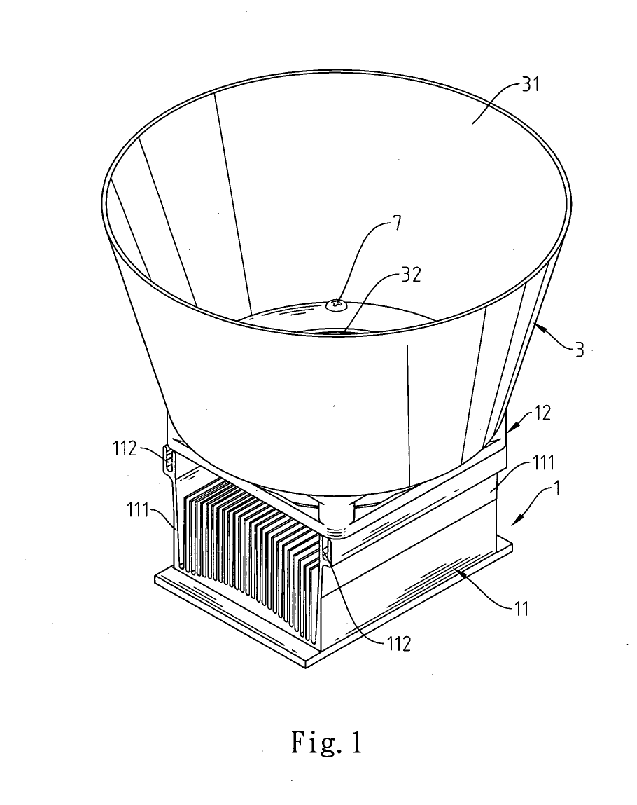

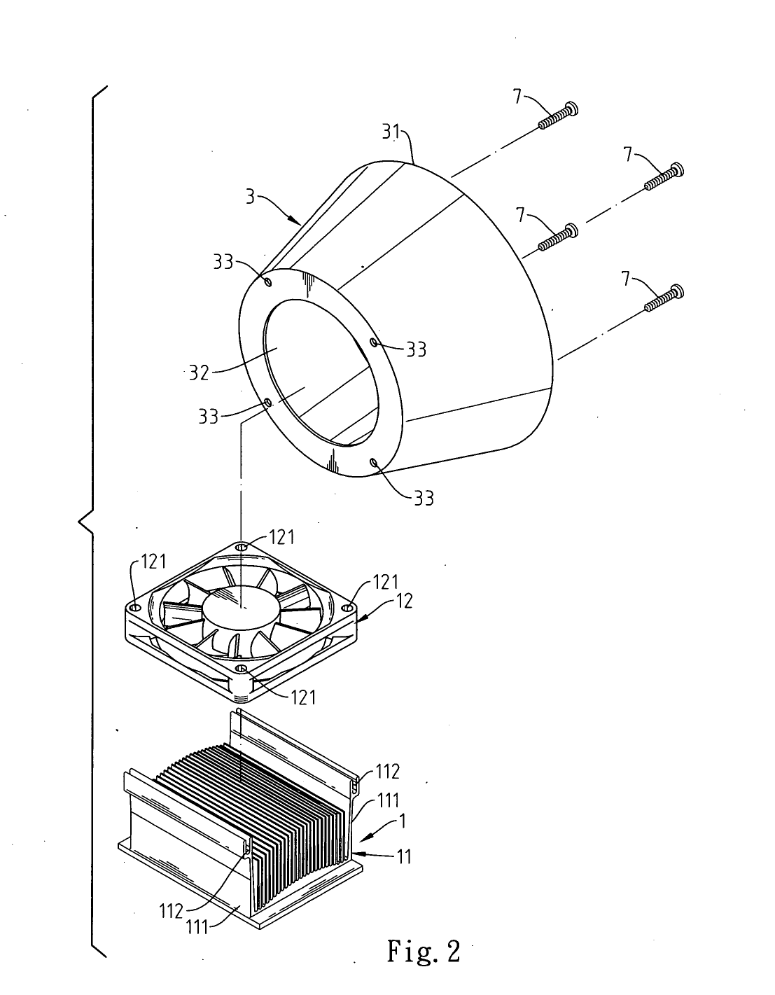

First, please refer to FIG. 1 to FIG. 3, above a mother board 5 inside a computer mainframe for this invention is installed with a CPU 6, a heat dissipation module 1, is then situated above CPU 6, comprising heat-dissipating fin 11 and fan 12, heat-dissipating fin 11 is in direct contact with CPU 6, it can take heat generated from CPU 6 away; the upper part of high and protruding side board body 111 located on both sides of heat-dissipating fin 11 is installed with open slot 112 which is to be installed with fan 12.

An air-guiding mask 3 is further installed above fan 12, air-guiding mask 3 is equipped with air-guiding end 31 in the front and combination part end 32 in the back wherein air-guiding end 31 can have a diameter larger than that of the combination part end 32 to form a cone-shaped body, or the diameters of the two ends can be the same, or even any other forms of combinations are allowed; there are through holes 33 located on 4 peripherals of combination part end 32, locking component 7 can be used to lock air-guiding mask 3 and fan 12 to the open slot 112 of heat-dissipating fin 11 by passing it through the through holes 33 on the air-guiding mask and through holes 121 on fan 12, a heat-dissipating module 1 formed by heat-dissipating fin 11 and fan 12 can thus be in tight combination with air-guiding mask 3.

The above-mentioned heat-dissipating module 1 is located at the side board of mainframe case 4, and since the mother board 5 inside the mainframe of normal computer is seated at one side of mainframe case 4, the CPU 6 is therefore also installed vertically as mother board 5. Multiple heat-dissipating holes 41 correspond to the CPU 6 location are opened on the mainframe case 4, when air-guiding mask 3 is combined in the heat-dissipating module 1, the air-guiding end 31 on air-guiding mask 3 can thus be correlated spatially to these heat-dissipating holes 41, therefore, when the fan 2 is running, it can bring cold air from outside and let it enter air-guiding mask 3, helping to cool the heat-dissipating fin 1 which has absorbed lots of heat generated by CPU 6.

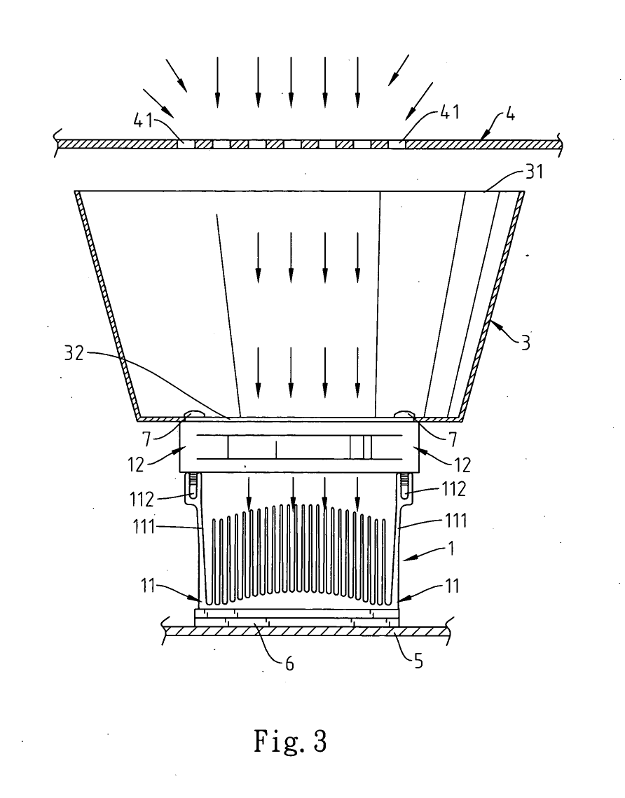

Although there is still gap between air-guiding mask 3 and mainframe case 4 as shown in FIG. 3, the hot air back flow is still limited because there is still certain distance between heat-dissipating hole 41 and the heat-dissipating module 1, hot air back flow thus won't affect the entrance of cold air.

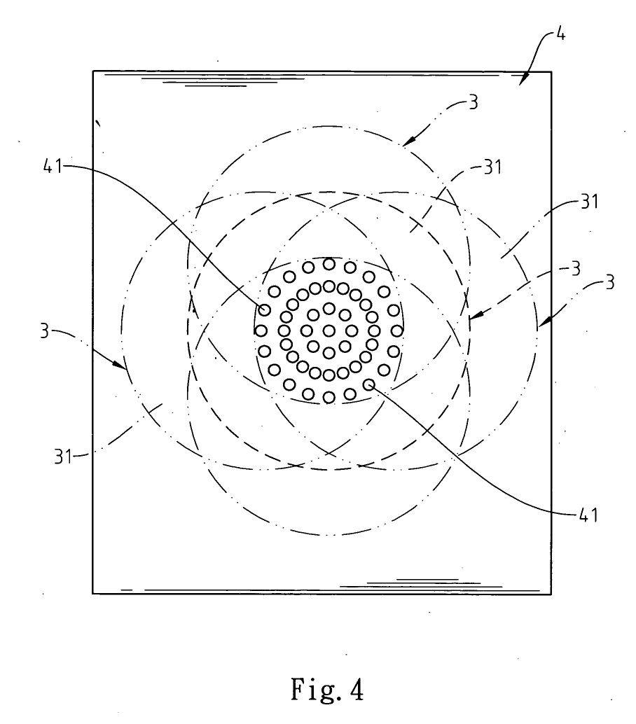

In addition, please refer to FIGS. 3 and 4, when mainframe case 4 is used in conjunction with different mother board 5, the location of CPU 6 installed on mother board 5 will be changed accordingly, therefore, when air-guiding mask 3 shift its location in accordance with CPU 6, it can still be correlated spatially to the heat-dissipating holes 41 on the mainframe case 4, cold air can still be introduced into the mainframe for heat dissipation, hot air within the mainframe case 4 can be prevented from backing flow into the heat-dissipating module 1 installed above CPU 6, therefore, this invention can easily solve the issues associated with the variations in mother board 5, heat-dissipating holes 41 all can be covered within air-guiding mask 3; in addition, if the area of heat-dissipating holes 41 covered by air-guiding mask 3 is greater than the entrance area of heat-dissipating fan 12, we can expect the air flow speed to be reduced, air resistance to be lowered, and the performance of heat-dissipating fan 12 to be enhanced, cold air can be sucked into the mainframe to effectively lower the temperature of CPU 6.

Furthermore, after real test, we find that the entrance point right before fan 12 installed above CPU 6 has a temperature of 46.4° C. when it is not installed with air-guiding mask 3, but that temperature is reduced to 36.4° C. when an air-guiding mask 3 is installed, therefore, heat exchange performed by exterior cold air introduced directly can effectively lower the high temperature on CPU 6.

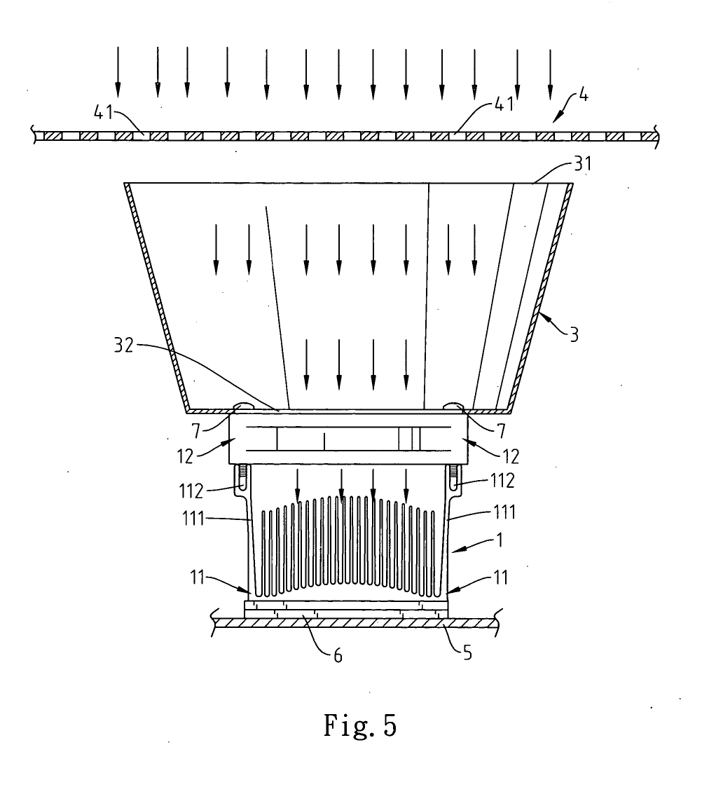

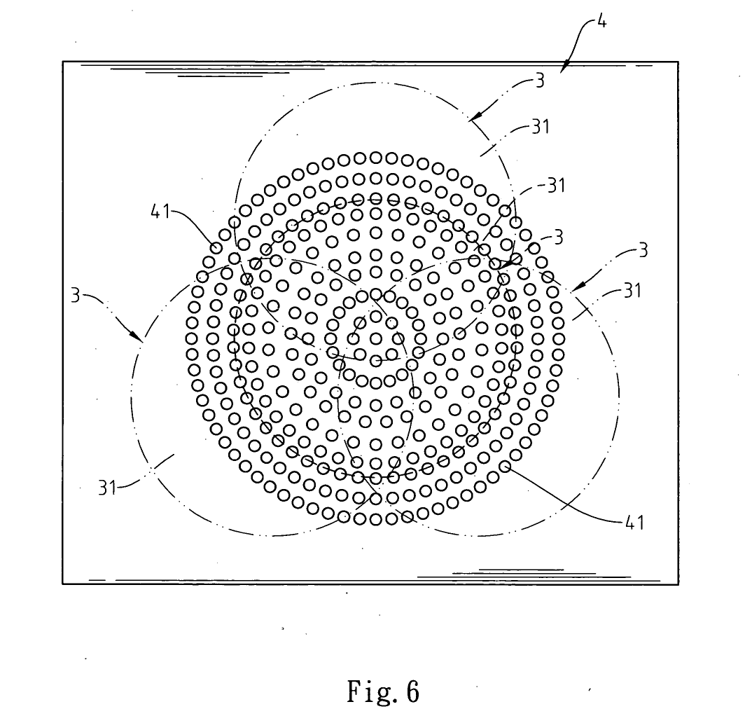

In addition, as shown in FIGS. 5 and 6, wherein the area of heat-dissipating holes 41 on mainframe case 4 is greater than that of air-guiding end 31 of air-guiding mask 3, and the intersection area between air-guiding mask 3 and heat-dissipating holes 41 is greater than that of the air entrance end of fan 12; therefore when the location of air-guiding mask 3 shifts together with the change of location of CPU 6, the air-guiding end 31 can still be correlated spatially to heat-dissipating holes 41 effectively; if the area of heat-dissipating holes 41 covered by air-guiding mask 3 is greater than that of the entrance end of fan 12, we can expect the air flow speed to be reduced, air resistance to be lowered, and the performance of heat-dissipating fan 12 to be enhanced, cold air can be sucked into the mainframe to effectively lower the temperature of CPU 6.

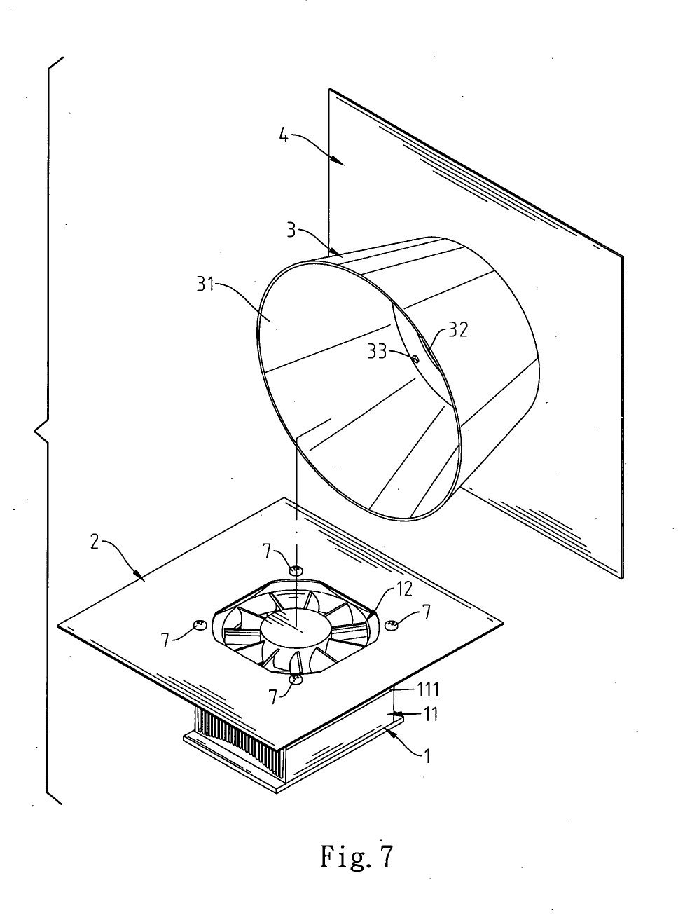

Please refer to FIG. 7 to FIG. 9 for another embodiment of the current invention wherein air-guiding mask 3 is fixed to the multiple heat-dissipating holes 41 on mainframe case 4 by combination part end 32, and the heat-dissipating fin 11 in the heat-dissipating module 1 is in contact and fixed to CPU 6 by locking component 7. When mother board 5 is seated vertically at one side of mainframe case 4, the CPU 6 will be seated vertically accordingly, and the air-guiding mask 3 fixed on the mainframe case 4 is then correlated to the heat-dissipating module 1 of CPU 6, the heat-dissipating module 1 installed above CPU 6 will have different height along with variations in mother board 5, therefore, the gap between heat-dissipating module 1 and the air-guiding mask 3 inside mainframe 4 will vary.

To prevent the issue of air back flow associated with the gap formed, and in turn the efficiency of temperature lowering and cooling efficiency of CPU 6, therefore, in the current embodiment a baffle 2 is locked above fan 12 of heat-dissipating module 1, the area of baffle 2 is greater than that of air-guiding end 31 of air-guiding mask 3, it can effectively increase the hot air back flow resistance. When fan 12 is running, the cold air taken in by air-guiding mask 3 will be directed into fan 2 to dissipate heat on the heat-dissipating fin 11; because there is a gap between air-guiding mask 3 and fan 12, part of the hot air will be sucked in again due to the operation of fan 12, at this time, baffle to function to increase the hot air back flow resistance, the hot air back flow re-sucking quantity caused by the existence of gap will then be greatly reduced.

We find from real experimental data for the current invention that when heat-dissipating structure was installed in the entrance of the fan of CPU inside the mainframe, the entrance has a temperature as high as 46.4° C., but when air-guiding mask 3 and the baffle 2 in front of heat-dissipating module 1 are installed, the entrance temperature is then reduced to 37.9° C., therefore, the direct heat exchange effect produced by exterior cold air can effectively reduce the heat produced by CPU 6.

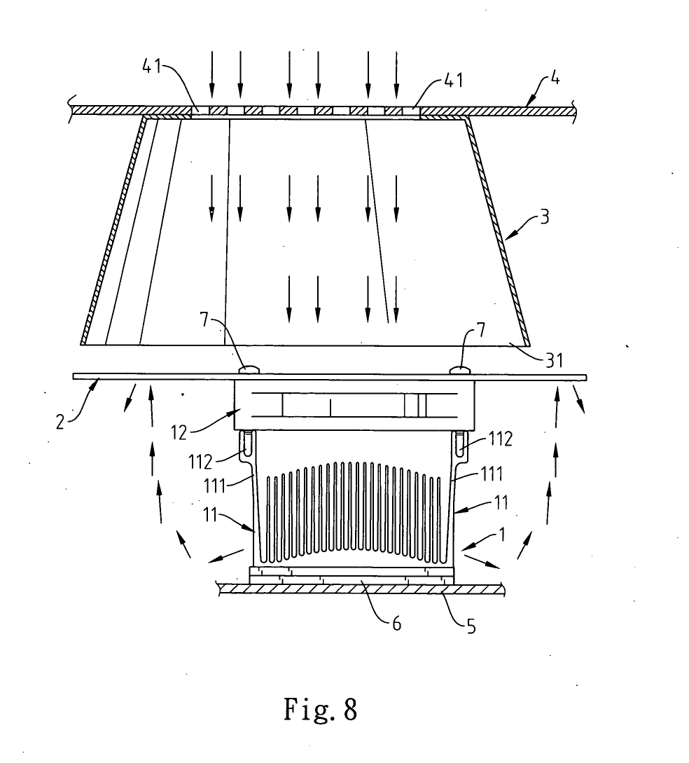

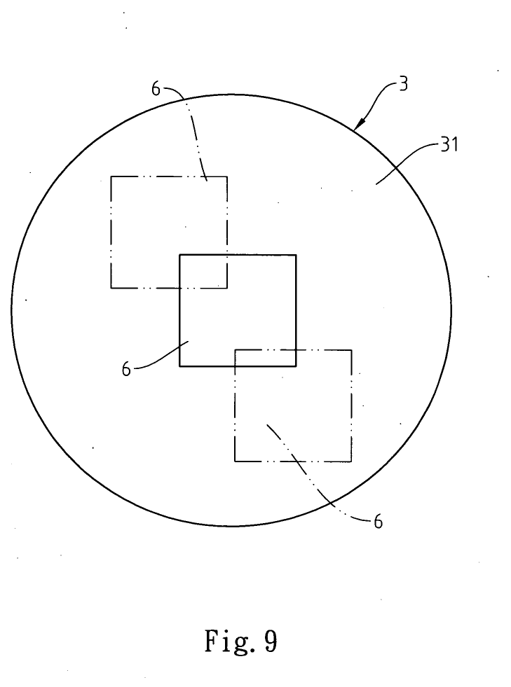

Please further refer to FIG. 8 and FIG. 9, when mainframe case 4 is used in conjunction with different mother board 5, the location of CPU 6 installed on mother board 5 will be changed accordingly therefore, when air-guiding mask 3 shift its location in accordance with CPU 6, it can still be correlated spatially to the heat-dissipating holes 41 on the mainframe case 4, cold air can still be introduced into the mainframe for heat dissipation.

To summarize the above descriptions, we find the heat-dissipating structure inside computer mainframe for the current invention can achieve the expected effect of reducing hot air back flow, it can be used in different kinds of mother boards, it possesses an universal feature and the advantage of lower cost, it has shorter time-to-the-market and has the saving of cost and time on building new molds, etc.; therefore, this invention does fit the requirements for the application of a patent, we thus submit a patent application. The above-mentioned are only some of the better embodiments for the current invention, for those skilled in the art can still make tiny modification or variation, they should all fall within the spirit and scope of the current invention.

1. A heat-dissipating structure inside computer mainframe, comprising mainly of an air-guiding mask and an associated heat-dissipating module installed in between mainframe case side board and the CPU situated on the mother board; the main features are:
the area of air-guiding end of air-guiding mask is greater than that of the heat-dissipating holes installed on mainframe case;
when mainframe case is used in conjunction with different mother board, the location of CPU installed on mother board will be changed accordingly, therefore, when the air guiding area of air-guiding mask can effectively cover the heat-dissipating holes on the mainframe case, cold air can be introduced into the mainframe for heat dissipation, and a direct cooling on CPU is thus performed.

2. The heat-dissipating structure inside computer mainframe of claim 1 wherein said air-guiding mask can be further fixed to the multiple heat-dissipating holes of mainframe case, a baffle is locked and bolted to the upper part of said heat-dissipating module, the baffle has an area greater than that of air-guiding end of air-guiding mask, it can effectively increase hot air back flow resistance, the hot air back flow re-sucking quantity can thus be greatly reduced, and partial hot air back flow phenomenon caused by the gap between air-guiding mask and heat-dissipating module is greatly eliminated.

3. A heat-dissipating structure inside computer mainframe comprising mainly an air-guiding mask and its associated heat-dissipating module between mainframe case and the CPU on the mother board; the main features are:
the area of air-guiding end of air-guiding mask is smaller than that of the heat-dissipating holes installed on mainframe case;
when mainframe case is used in conjunction with different mother board, the location of CPU installed on mother board will be changed accordingly, therefore, when the intersection area between the air-guiding end of air-guiding mask is greater than that of the entrance end of the fan, cold air can be introduced into the mainframe for heat dissipation effectively, and a direct cooling on CPU is thus performed.
